(19) United States
(12) Patent Application Publication
(10) Pub. No.: US 2005/0174042 A1
(43) Pub. Date: Aug. 11, 2005

(54) Display panel and method for manufacturing display panel

(76) Inventors: Ryuji Nishikawa, Gifu-shi (JP); Tetsuji Omura, Ogaki-shi (JP)

Correspondence Address: MCCARTER & ENGLISH LLP;CITYPLACE I, 185 ASYLUM STREET, HARTFORD, CT, 06103, US

(21) Appl. No.: 11/035,464

(22) Filed: Jan. 13, 2005

(30) Foreign Application Priority Data
Jan. 16, 2004 (JP) 2004-9872

(51) Int. Cl. H01J 1/62

(52) U.S. Cl. 313/500

(57) ABSTRACT

A sealing substrate is placed opposing an EL substrate with a predetermined gap therebetween. The sealing substrate is nontransparent. A laser irradiation region of a terminal portion of the EL substrate is formed by a transparent conductor such as ITO. With this structure, a periphery region of the sealing substrate is irradiated with laser through the EL substrate and heated, so that glass is elevated and welded.

### CROSS-REFERENCE TO RELATED APPLICATIONS

The entire disclosure of Japanese Patent Application No. 2004-9872 including specification, claims, drawings and abstract is incorporated herein by reference.

### BACKGROUND OF THE INVENTION

1. Field of the Invention

The present invention relates to manufacture of a display panel such as an organic electroluminescence (hereinafter simply referred to as “EL”) display panel and, in particular, to a sealing structure in the display panel.

2. Description of the Related Art

Plasma display panels (PDP) and liquid crystal display devices (LCD) are becoming widely available as thin flat display panels and organic EL panels are commercially available.

In an organic EL panel, an organic material is used as a light emitting material in each pixel or the like. Because the lifetime of the organic material is shortened when the organic material contains moisture, it is necessary to minimize an amount of moisture in a space in which the pixel is present. For this purpose, a sealing substrate is disposed to oppose, with a predetermined gap, an EL substrate on which display pixels including organic EL elements are formed in a matrix form and the peripheral portion of the substrates is air-tightly sealed with a seal material made of a resin to prevent moisture from intruding into the inside. In addition, a desiccant is provided in the inside space to remove moisture.

As the sealing material, an epoxy-based ultraviolet curable resin or the like is used. However, there is a demand for further improving the air-tightness.

Normally, a glass substrate is used as the EL substrate and as the sealing substrate. For joining glass structures, there is a method for fusing the glass through heating and joining the glass structures. It can be considered that a sealing with a higher air tightness than the sealing by a resin sealing material can be realized using this sealing process of glass. In particular, it may be possible to join the peripheral portions of glass substrates through welding of glass using laser light. Joining of glass using laser light is disclosed in, for example, Japanese Patent Laid-Open Publication No. 2003-170290.

A terminal portion for receiving a video signal or the like from external devices is present in the peripheral portion of the EL substrate. This terminal portion must be exposed to the outside for connection with the external devices. Therefore, a terminal or a line must cross the sealing portion in the EL substrate. However, because the terminal and line are typically made of a metal such as aluminum and does not allow laser light to transmit, there is a problem in that the welding of glass in this portion cannot be achieved.

### SUMMARY OF THE INVENTION

According to the present invention, a pixel substrate and a sealing substrate are joined through welding by laser irradiation. With this structure, it is possible to achieve reliable sealing with a small area, which allows for an increase in an area of the display region in which the display can actually be realized and a smaller display size. In addition, because the joining is achieved through welding, it is possible to reliably prevent intrusion of moisture and the amount of desiccant to be sealed in the inside space can be reduced or the desiccant may be omitted. Moreover, it is possible to allow laser to transmit through the line portion on the pixel substrate through which the laser transmits, by forming the line portion with a transparent conductor.

### BRIEF DESCRIPTION OF THE DRAWINGS

A preferred embodiment of the present invention will be described in detail based on the following drawings, wherein:

FIG. 1 is a diagram showing a structure of a peripheral portion of an EL substrate and a sealing substrate;

FIG. 2 is a diagram showing laser irradiation;

FIG. 3 is a diagram showing a position of a sealing portion;

FIG. 4 is a diagram showing a structure of a pixel in a bottom emission type structure;

FIG. 5 is a diagram showing a placement of a nontransparent region;

FIG. 6 is a diagram showing a structure of a pixel in a top emission type structure;

FIG. 7 is a diagram showing a circuit structure; and

FIG. 8 is a diagram showing a structure of a laser transmissive portion.

### DESCRIPTION OF PREFERRED EMBODIMENT

A preferred embodiment (hereinafter, referred to simply as “embodiment”) of the present invention will now be described referring to the drawings.

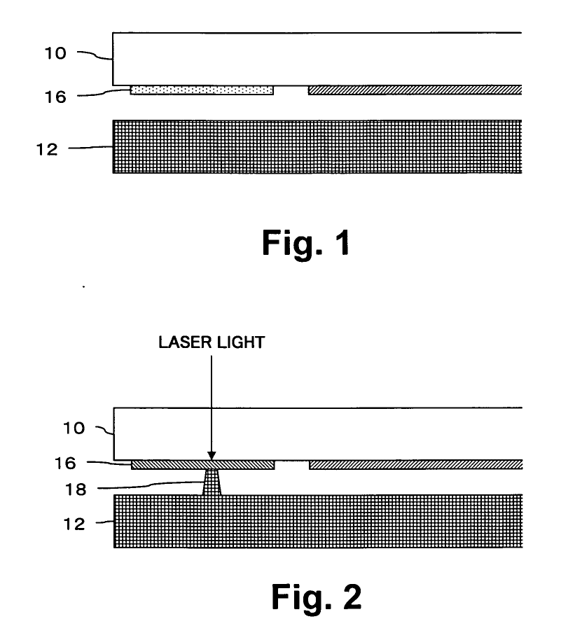

FIGS. 1 and 2 show joining of substrates according to a preferred embodiment of the present invention. An EL substrate 10 which is a pixel substrate on which a pixel or pixels are formed and a sealing substrate 12 for sealing an upper surface of the EL substrate 10 are placed opposing each other. The sealing substrate 12 is made of an absorbing structure which absorbs laser, such as nontransparent glass. Here, the entire region of the sealing substrate 12 need not be nontransparent, but it is necessary that the portion to be welded functions as an absorbing structure. For example, the sealing substrate 12 can be made nontransparent by doping a metal though an ion injection or ion exchange method, for example, and the nontransparent substrate 12 functions as an absorbing structure. In the ion exchange method, a resist which is patterned so as to expose the portion to become a nontransparent region is formed on the sealing substrate 12 and the structure is immersed in a solution containing a predetermined metal to exchange the ions in the sealing substrate 12 (for example, sodium) to diffuse the metal into the sealing substrate 12 to make the sealing substrate 12 an absorbing structure. In any method, as shown in the drawings, although it is possible to form the entire thickness of the sealing substrate 12 to be nontransparent, it is also possible to form only the surface portion of the sealing substrate 12 within a predetermined depth from the surface to be nontransparent.

It is also possible to form an absorbing structure on the sealing substrate 12. For example, it is possible to layer a nontransparent material such as a metal on the sealing substrate 12 through, for example, vacuum evaporation, CVD (Chemical Vapor Deposition), or sputtering, or to apply a colored paint on the sealing substrate 12. In addition, because the absorbing structure needs be present at the interface, it is possible to form the absorbing structure on the side of the pixel substrate when such a configuration does not cause a problem.

In the present embodiment, copper is used as the metal to be used in the absorbing structure, but the present invention is not limited to copper and other nontransparent metals such as silver, iron, etc. may be used. An optical transmissivity of a nontransparent region 14 is, for example, preferably approximately 1%-2% for light having a wavelength of 550 nm. When the optical transmissivity is 8% or greater, an amount of absorption of light is small and the portion to be heated cannot be heated to a sufficient degree.

The EL substrate 10 and the sealing substrate 12 are then fixed with a gap of 6 μm-10 μm, more preferably, approximately 8 μm therebetween and laser light is irradiated from the side of the EL substrate 10 in this state. When the laser is a YAG laser (1064 nm), a power of approximately 10 W to 50 W is employed.

With this process, light is absorbed in the region of the sealing substrate 12 irradiated with the laser and this region is fused through heating. It is preferable that the laser irradiated region is heated to a temperature of approximately 600° C. to 700° C. With this process, the laser irradiated region of the sealing substrate 12 is fused and this portion is elevated. The tip of the elevated portion contacts the EL substrate 10 and is welded. Typically, a laser light of a spot shape is used and the irradiated area is scanned with the spot so that the EL substrate 10 and the sealing substrate 12 are sealed at their peripheral portions through welding.

A large portion of the EL substrate 10 is dedicated as a display region in which display pixels are disposed in a matrix form and a driver or the like is disposed in the peripheral portion. A terminal portion 16 for connection with the external device is provided because a video signal, power supply, etc. are supplied from the outside. The terminal portion 16 comprises a plurality of pad portions for connection to the outside and a plurality of line portions for electrical connection with the internal circuit are connected to the pad portions.

The pads and the line portions to be connected to the pads in the terminal portion 16 are normally formed of a metal such as aluminum, but the portion of the pads and line portions in the terminal portion 16 which must allow laser to transmit is made of ITO, which is a transparent conductor.

Therefore, as shown in FIG. 2, in the terminal portion 16 also, the sealing substrate 12 is irradiated with the laser light through the EL substrate 10, the laser irradiated region is heated, the sealing portion 18 is elevated, and the substrates 10 and 12 are sealed through glass welding.

In this manner, the EL substrate 10 and the sealing substrate 12 can be welded through glass welding using laser light. With the laser irradiation, because only the portion to be welded is heated and the internal space created by the sealing process is heated to only a small extent, the temperatures of the internal space and the temperature of the external space do not significantly change. Therefore, it is easy to set the pressure inside the internal space after sealing to an appropriate value. In addition, because the sealing process is executed in a nitrogen atmosphere which has substantially no moisture and the sealing by glass welding results in a very high degree of air tightness, the probability of moisture intruding into the internal space is low during use in an atmosphere after the substrates are sealed. Thus, it is not necessary to provide a desiccant in the internal space, and, even if a desiccant is provided, the amount of the desiccant can be significantly reduced. Moreover, when the glass welding process using laser light is employed, the width of the joining portion between the EL substrate 10 and the sealing substrate 12 is small. Therefore, it is possible to reduce an area of the sealing region at the peripheral portion of the EL substrate and to reduce the size of the display panel.

In the present embodiment, the laser transmissive portion of the EL substrate 10 is transparent including the terminal portion 16. Therefore, it is possible to irradiate the peripheral region of the sealing substrate 12 with a laser light in a shape of rectangular frame through the EL substrate 10 to form a sealing portion 18 having a rectangular frame shape to seal the substrates 10 and 12.

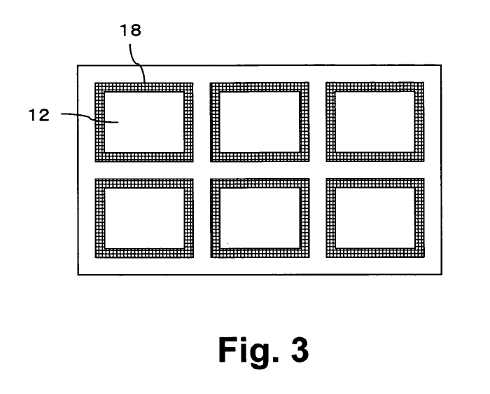

FIG. 3 shows a state in which a plurality (in the illustrated configuration, 6) of display panel portions are provided on one glass substrate. As illustrated, sealing portions 18 having a rectangular frame shape are formed on a glass substrate with a predetermined spacing. The structure is then separated into each separate display panel by a laser cutter. In this manner, a plurality of EL substrates 10 can be manufactured together in the same steps, which allows for effective process of affixing and cutting, each as one step.

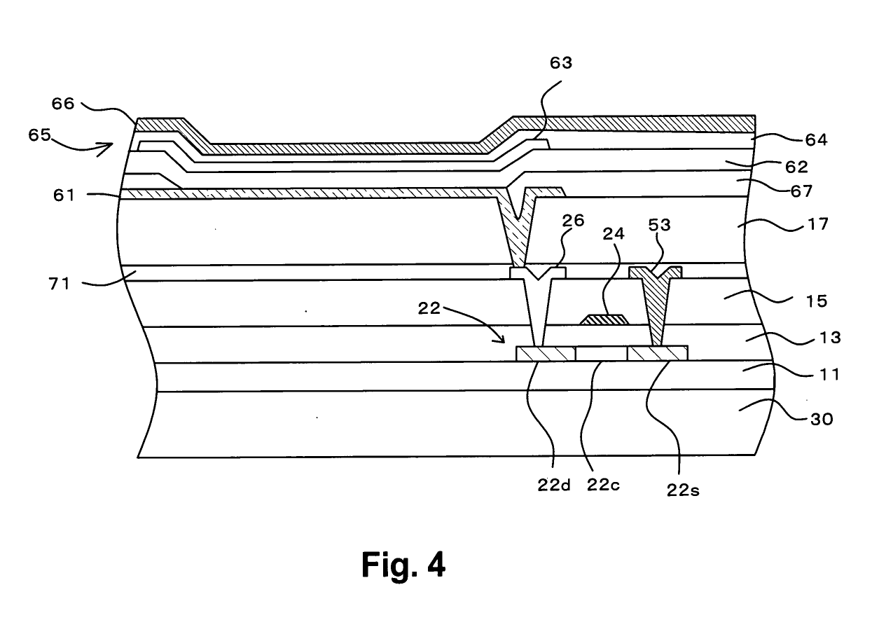

FIG. 4 is a cross sectional diagram showing a structure of a portion of a light emitting region and a driver TFT within one pixel. A plurality of TFTs are provided in each pixel. A driver TFT is a TFT which controls a current to be supplied from a power supply line to an organic EL element. A buffer layer 11 having a layered structure of SiN and SiO₂ is formed over the entire surface of the glass substrate 30 and a polysilicon active layer 22 is formed on the buffer layer 11 in a predetermined area (area in which a TFT is to be formed).

A gate insulating film 13 is formed over the entire surface covering the active layer 22 and the buffer layer 11. The gate insulating film 13 is formed by, for example, layering SiO₂ and SiN. A gate electrode 24 made of, for example, Cr is formed above the gate insulating film 13 in positions above a channel region 22c. Using the gate electrode 24 as a mask, impurities are doped into the active layer 22 so that a channel region 22c in which no impurity is doped is formed in the active layer 22 below the gate electrode which is at the center and a source region 22s and a drain region 22d which are doped with the impurities are formed in the active layer 22 on both sides of the channel region 22c.

An interlayer insulating film 15 is formed over the entire surface covering the gate insulating film 13 and the gate electrode 24, a contact hole is formed through the interlayer insulating film 15 in positions above the source region 22s and the drain region 22d, and a source electrode 53 and a drain electrode 26 to be placed on an upper surface of the interlayer insulating film 15 is formed through the contact hole. A power supply line (not shown) is connected to the source electrode 53. In the illustrated configuration, the driver TFT formed in this manner is a p-channel TFT, but the driver TFT may alternatively be an n-channel TFT.

A planarizing film 17 is formed over the entire surface covering the interlayer insulating film 15, source electrode 53, and drain electrode 26. A transparent electrode 61 which functions as an anode is provided on an upper surface of the planarizing film 17 at a position corresponding to the light emitting region. A contact hole is formed through the planarizing film 17 above the drain electrode 26 and the drain electrode 26 and transparent electrode 61 are connected through the contact hole.

Normally, SiO₂ or SIN is used for the interlayer insulating film 15 and an acrylic resin or the like is used for the planarizing film 17. It is also possible to use TEOS or the like. The source electrode 53 and drain electrode 26 are made of a metal such as aluminum, and, normally, ITO is used for the transparent electrode 61.

Typically, the transparent electrode 61 is formed in a large portion of each pixel and has an overall shape of an approximate rectangle. A contact portion for connection to the drain electrode 26 is formed as a protruding section which extends into the contact hole.

An organic layer 65 having a hole transport layer 62 which is formed over the entire surface, an organic light emitting layer 63 which is formed in a size slightly larger than the light emitting region, and an electron transport layer 64 which is formed over the entire surface is formed above the transparent substrate 61. An opposing electrode 66 formed over the entire surface and made of a metal (such as aluminum) is formed above the organic layer 65 as a cathode.

A planarizing film 67 is formed on a peripheral portion of the transparent electrode 61 and below the hole transport layer 62 so that the light emitting region of each pixel is limited to a portion above the transparent electrode 61 and in which the hole transport layer 62 is directly in contact with the transparent electrode 61. Typically, an acrylic resin or the like is used for the planarizing film 67, but it is also possible to use TEOS or the like.

For the hole transport layer 62, organic light emitting layer 63, and electron transport layer 64, materials which are typically used for an organic EL element are used and the light emission color is determined corresponding to the material (normally, a dopant) in the organic light emitting layer 63. For example, NPB or the like is used for the hole transport layer 62, TBADN +DCJTB or the like is used for the organic light emitting layer 63 of red color, Alq₃+CFDMQA or the like is used for the organic light emitting layer 63 of green color, TBADN+TBP or the like is used for the organic light emitting layer 63 of blue color, and Alq₃ or the like is used for the electron transport layer 64.

In this structure, when the driver TFT is switched on corresponding to a voltage which is set on the gate electrode 24, a current from the power supply line flows from the transparent electrode 61 to the opposing electrode 66, and light emission is achieved in the organic light emitting layer 63 due to the current and is emitted toward bottom of FIG. 4.

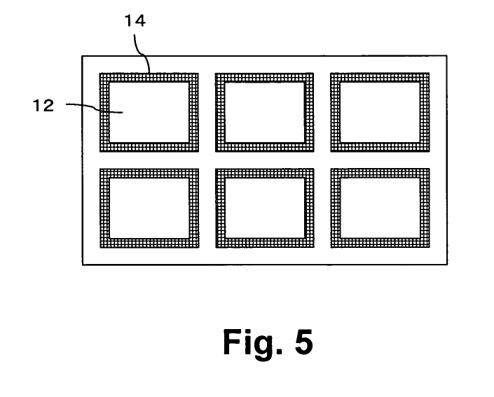

FIG. 5 shows another structure. In this configuration, a nontransparent region 14 is formed as an absorbing structure in a frame shape corresponding to the peripheral portion of the EL panel. Therefore, by irradiating the nontransparent region 14 with laser, it is possible to achieve glass welding similar to the above-described configuration. In this configuration, a portion of the sealing substrate 12 corresponding to the display region of the EL substrate 10 is transparent. Therefore, it is possible to emit light through the sealing substrate 12 to realize a top emission type display panel.

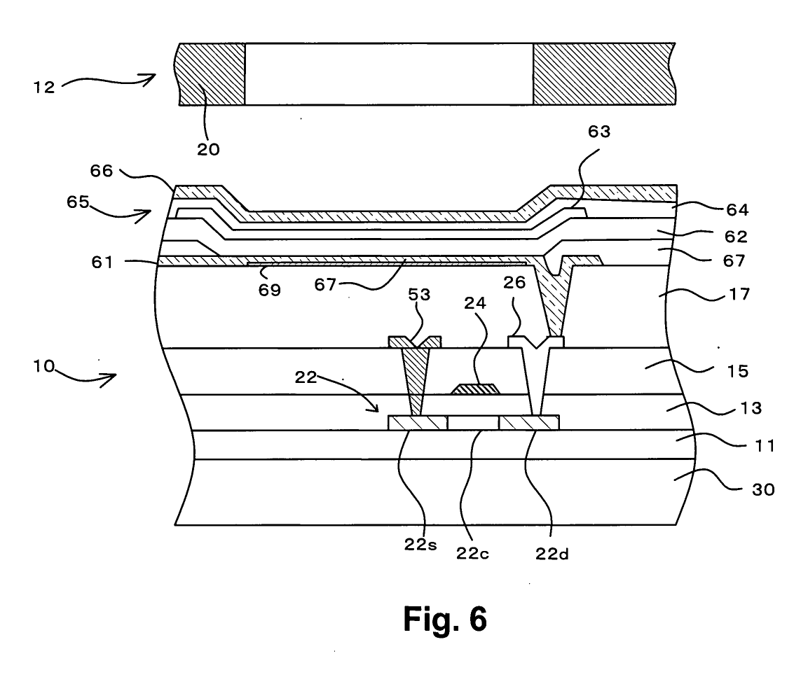

FIG. 6 shows a structure of a pixel portion in a top emission type display panel. As shown in FIG. 6, a reflective film 69 is formed below the transparent electrode 61. The reflective film 69 is formed of silver or the like. The opposing electrode 66, on the other hand, is formed of a transparent conductor such as ITO. Therefore, the light created in the organic layer is reflected by the reflective film 69 and is emitted through the opposing electrode 66 toward the top of FIG. 6. The portion of the sealing substrate 12 corresponding to the display region is transparent and the light is emitted through the sealing substrate 12 to the outside.

In this configuration, a black matrix 20 is formed in a boundary between pixels so that a clearer display can be obtained. The black matrix 20 is preferably formed in the same process as that for the nontransparent region 18.

By employing a top emission type structure, it is possible to also form a light emitting region above the TFT, and therefore, it is possible to easily form a bright panel with a high aperture ratio (percentage of light emitting region) even when a pixel circuit having a plurality of TFTs is used.

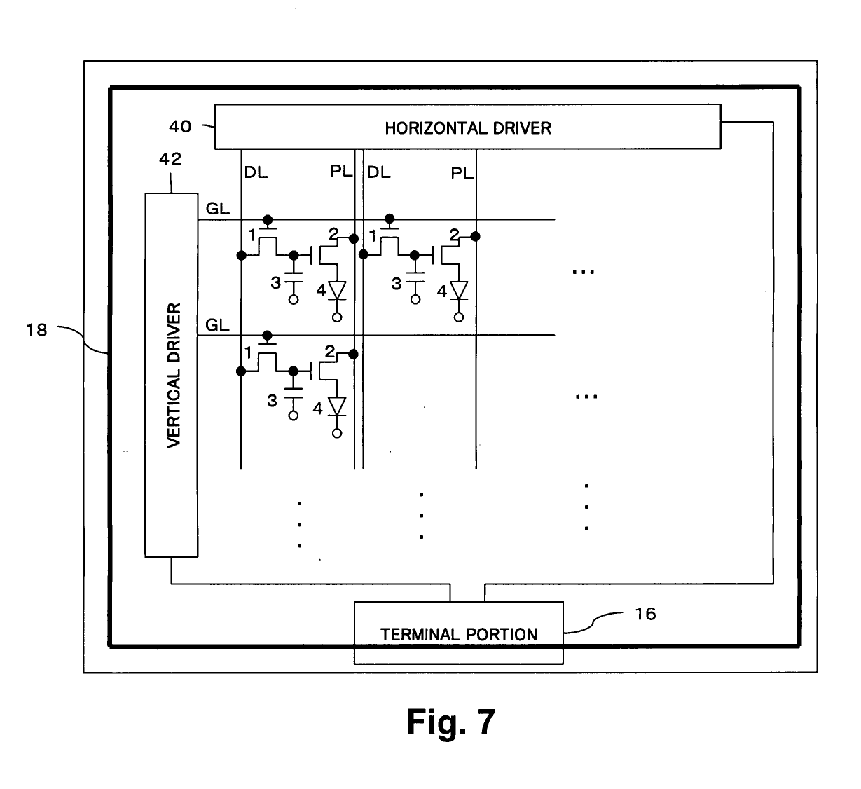

FIG. 7 schematically shows a circuit on the EL substrate 10. A horizontal driver 40 and a vertical driver 42 are provided as peripheral circuits and the internal region forms the display region. A data line DL and a power supply line PL are provided from the horizontal driver 40 along a vertical direction corresponding to pixels of each column and a gate line GL is provided from the vertical driver along the horizontal direction corresponding to pixels of each row. A power supply voltage, an operation clock, and video data are supplied to the horizontal driver 40 and vertical driver 42 from external devices through the terminal portion.

Each pixel comprises an n-channel selection TFT 1, a p-channel driver TFT 2, a storage capacitor 3, and an organic EL element 4. A drain of the selection TFT 1 is connected to a data line DL, a gate of the selection TFT 1 is connected to a gate line GL, and a source of the selection TFT 1 is connected to a gate of the driver TFT 2. One terminal of the storage capacitor 3 is connected to the gate of the driver TFT 2 and the other terminal of the storage capacitor 3 is connected to an SC capacitor line having a predetermined potential. A source of the driver TFT 2 is connected to a power supply line PL and a drain of the driver TFT 2 is connected to an anode of the organic EL element 4. A cathode of the organic EL element 4 is connected to a cathode power supply having a low voltage.

When the gate line GL is set to H, the selection TFT 1 on the corresponding row is switched on. In this state, when a data voltage is set on the data line DL, the data voltage is stored in the storage capacitor 3, the driver TFT 2 allows a current corresponding to the data voltage to flow from the power supply line PL through the organic EL element 4, and light is emitted corresponding to the data voltage.

As shown in the figure by a bold line, a sealing portion 18 is formed at the periphery in a rectangular frame shape. In particular, the sealing portion 18 is also formed above the terminal portion. Because the conductor of the terminal portion 16 at positions corresponding to the sealing portion 18 is formed of a transparent conductor such as ITO and IZO as described above, in these positions also, the laser light can transmit through the EL substrate 10.

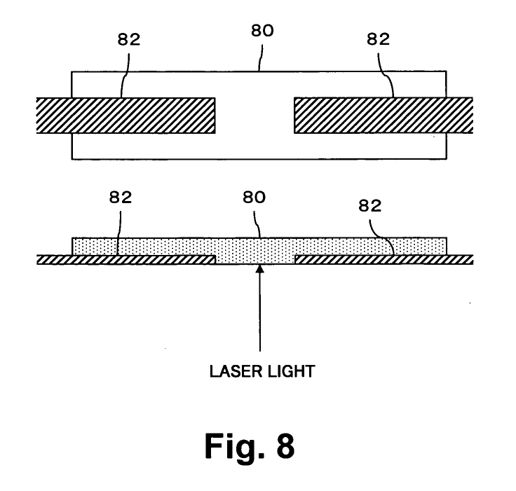

FIG. 8 exemplifies a structure at the terminal portion 16. In this configuration, only the conductor portion 80 through which laser is to transmit is formed of ITO and the other conductor portions 82 are formed of aluminum. More specifically, a laser transmissive portion of the conductor portion 82 made of aluminum is cut and a conductor portion 80 made of ITO is formed covering this portion to maintain the electrical connection.

In the foregoing description, the laser transmissive portion is provided in the terminal portion 16. It is also possible to form a part of a line portion to the terminal portion by a transparent conductor such as ITO to realize a laser transmissive portion.

The present invention is not limited to the configuration described above, as long as a configuration allows transmission of laser light through and heating of a nontransparent portion of the sealing substrate 12 in the line portion such as a terminal portion 16 on the EL substrate 10. For example, it is also possible to form a metal line with a mesh shape to allow laser to partially transmit through or to reduce the thickness to realize a semitransparent structure.

As described, in the present embodiment, a glass substrate is used as the EL substrate 10 and as the sealing substrate 12. However, the material of the substrates is not limited to glass as long as the sealing substrate 12 or the absorbing structure formed on the sealing substrate 12 absorbs laser and welding by the laser energy is enabled. For example, it is possible to use various resin films or metal films as the substrate.

1. A manufacturing method of a display panel, wherein
the display panel comprises a pixel substrate which is made of a material which allows laser to transmit and having a display region in which a plurality of display pixels are formed in a matrix form and a periphery region surrounding the display region and a sealing substrate which is placed opposing the pixel substrate,
a line present in the periphery region of the pixel substrate and in a portion which allows laser to transmit is formed by a transparent conductor, and
a junction interface between the pixel substrate and the sealing substrate is sealed through welding by irradiation of laser.

2. A manufacturing method of a display panel according to claim 1, wherein
the transparent conductor is ITO or IZO.

3. A manufacturing method of a display panel according to claim 1, wherein
an absorbing structure which absorbs laser is formed at the junction interface, and
the sealing through welding is effected by the absorbing structure absorbing the laser and being heated.

4. A manufacturing method of a display panel according to claim 3, wherein
the absorbing structure is formed by doping a nontransparent material into the sealing substrate or through film formation of a nontransparent material on the sealing substrate by vacuum evaporation, sputtering, CVD, or application..

5. A manufacturing method of a display panel according to claim 4, wherein
the nontransparent material is a metal.

6. A manufacturing method of a display panel according to claim 1, wherein
the material which allows laser to transmit is glass.

7. A display panel comprising:
a pixel substrate formed by a material which allows laser to transmit and having a display region in which a plurality of display pixels are formed in a matrix form and a periphery region which surrounds the display region, and
a sealing substrate having a junction interface with the pixel substrate sealed through welding by laser irradiation, wherein
a line present in the periphery region of the pixel substrate and in a portion which allows laser to transmit is made of a transparent conductor.

8. A display panel according to claim 7, wherein
the transparent conductor is ITO or IZO.

9. A display panel according to claim 7, wherein
an absorbing structure which absorbs laser is formed in the junction interface.

10. A display panel according to claim 9, wherein
the absorbing structure is formed by doping a nontransparent material into the sealing substrate or through film formation of a nontransparent material on the sealing substrate by vacuum evaporation, sputtering, CVD, or coating.

11. A display panel according to claim 10, wherein
the nontransparent material is a metal.
